(19) United States
(12) Patent Application Publication
(10) Pub. No.: US 2022/0348790 A1
(43) Pub. Date: Nov. 3, 2022

(54) CHEMICAL MECHANICAL POLISHING COMPOSITION AND METHOD

(71) Applicant: Rohm and Haas Electronic Materials CMP Holdings, Inc., Newark, DE (US)

(72) Inventors: Changzai Chi, Hockessin, DE (US); Kwadwo Tettey, Bear, DE (US); Matthew Richard Van Hanehem, Middletown, DE (US); Murali Ganth Theivanayagam, Newark, DE (US); Li Zhang, Glen Mills, PA (US); David Wayne Mosley, Philadelphia, PA (US)

(21) Appl. No.: 17/697,709

(22) Filed: Mar. 17, 2022

Related U.S. Application Data
(60) Provisional application No. 63/178,053, filed on Apr. 22, 2021.

(51) Int. Cl. C09G 1/02; C08K 3/36; C08K 9/06

(52) U.S. Cl. CPC C09G 1/02; C08K 3/36; C08K 9/06

(57) ABSTRACT

Chemical mechanical polishing compositions include modified silanized colloidal silica particles which are reaction products of silanized colloidal silica particles having epoxy moieties with nitrogen of amines to form stable and tunable modified silanized colloidal silica particles. The modified silanized colloidal silica particles can be used as an abrasive in chemical mechanical polishing of various substrates to polish metal such as copper, Ta and TaN and dielectrics such as TEOS and low-K film.

### FIELD OF THE INVENTION

The present invention is directed to a chemical mechanical polishing composition and method for polishing a substrate, wherein the chemical mechanical polishing composition includes surface modified silanized colloidal silica particles. More specifically, the present invention is directed to a chemical mechanical polishing composition and method for polishing a substrate with surface modified silanized colloidal silica particles, wherein the surface modified silanized colloidal silica particles are reaction products of epoxy moieties of silanized colloidal silica particles with nitrogen of amine compounds and the substrate includes copper and dielectric materials such as TEOS.

### BACKGROUND OF THE INVENTION

Aqueous colloidal silica particle dispersions have long been used in chemical mechanical polishing (CMP) slurries as abrasive particles to polish metals and dielectric materials. Slurries containing negatively charged and positively charged silica particles for polishing copper barriers slurries are known in the art. Such copper barrier slurries using negatively charged silica can operate in an alkaline region at pH values above 10. Examples of such slurries are disclosed in U.S. Pat. Nos. 6,916,742 and 7,785,487. At alkaline pH, both colloidal silica abrasive particles and dielectric substrates are negatively charged. Such slurries require high weight percent abrasives to achieve high throughput.

Two major disadvantages of using high weight percent abrasives include high material cost and high defectivity. To overcome these disadvantages, copper barrier slurries using positively charged silica particles have also been proposed. For example, U.S. Pat. No. 7,018,560 discloses a copper barrier polishing composition which includes an organic-containing quaternary ammonium salt to reverse the charge of silica particle. However, this approach relies on adsorption of quaternary ammonium species onto negatively charged particles. Usually an excess amount of quaternary ammonium is needed, and the pH should be kept below 5 to maintain positive charge and good stability of particles. Similarly, U.S. Pat. No. 8,715,524 discloses a polishing liquid for polishing a barrier layer comprising a diquaternary ammonium cation and a colloidal silica with pH in the range of 2.5 to 5.0.

Entrapping nitrogen-containing compounds within silica particles has been used to increase positive charge. U.S. Pat. No. 9,556,363 discloses a slurry composition which includes colloidal silica abrasive particles having a nitrogen-containing compound such as an aminosilane or a phosphorus-containing compound incorporated therein. The pH of slurries should be acidic to maintain positive charge and slurry stability. Such nitrogen entrapping processes add an additional process complexity and increased cost to silica particles.

Aminosilane modified colloidal silica particles also have been used in copper barrier slurries. U.S. Pat. No. 8,252,687 discloses a barrier slurry composition containing silica, an amine-substituted silane, a tetraalkylammonium salt, a tetraalkylphosphonium salt, and an imidazolium salt, a carboxylic acid having seven or more carbon atoms and a pH below 6. However, surface modification using aminosilanes has its own deficiency. Aminosilanes are self-catalytic and it's often difficult to control reaction kinetics which can led to particle aggregation.

U.S. 20200024483 discloses a pH neutral to high alkaline aqueous dispersion for chemical mechanical polishing which includes silica particles and amino group-containing silane compounds and condensates. However, TEOS removal rates of such composition are very low.

Accordingly, there is a need for improved chemical mechanical polishing compositions and methods for polishing copper and dielectric materials.

### SUMMARY OF THE INVENTION

The present invention is directed to a chemical mechanical polishing composition comprising a silanized colloidal silica particle comprising a reaction product of an epoxy functionality of the silanized colloidal silica particle with a nitrogen of an amine;

water;
optionally a chelating agent;
optionally a corrosion inhibitor;
optionally an oxidizing agent;
optionally a source of iron (III) ions;
optionally a surfactant;
optionally a defoaming agent;
optionally biocide; and
optionally a pH adjustor.

The present invention is further directed to a chemical mechanical polishing method comprising: providing a substrate comprising copper and TEOS;

providing a chemical mechanical polishing composition comprising a silanized colloidal silica particle, wherein the silanized colloidal silica particle comprises a reaction product of an epoxy functionality of the silanized colloidal silica particle with a nitrogen of an amine;
water;
optionally a chelating agent;
optionally a corrosion inhibitor;
optionally an oxidizing agent;
optionally a source of iron (III) ions;
optionally a surfactant;
optionally a defoaming agent;
optionally biocide; and
optionally a pH adjustor;
providing a chemical mechanical polishing pad, having a polishing surface; creating dynamic contact at an interface between the chemical mechanical polishing pad and the substrate; and dispensing the chemical mechanical polishing composition onto the polishing surface of the chemical mechanical polishing pad at or near the interface between the chemical mechanical polishing pad and the substrate; wherein at least some of the copper and the TEOS are polished away from the substrate.

The present invention is also directed to a chemical mechanical polishing composition comprising:

a silanized colloidal silica particle having the structure:

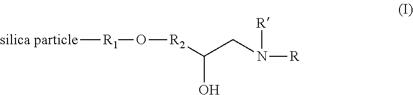

wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups of the substituted amino alkyl include linear or branched C₁-C₄ alkyl group on the nitrogen of the amino alkyl group, substituted or unsubstituted guanidyl group, wherein substituent groups on the substituted guanidyl group are chosen from C₁-C₂ alkyl on a nitrogen of the guanidyl group, and R′ and R independently can be a moiety having the formula:

H₂N—[—(CH₂)ₙ—NH-]ₘ—(CH₂)ₙ— (II)

wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups;
water;
optionally a chelating agent;
optionally a corrosion inhibitor;
optionally an oxidizing agent;
optionally a source of iron (III) ions;
optionally a surfactant;
optionally a defoaming agent;
optionally biocide; and
optionally a pH adjustor.

The present invention is additionally directed to a chemical mechanical polishing method comprising: providing a substrate comprising copper and TEOS;

providing a chemical mechanical polishing composition comprising:
a silanized colloidal silica particle having the structure:

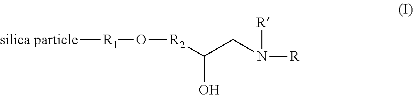

wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups of the substituted amino alkyl include linear or branched C₁-C₄ alkyl on the nitrogen of the amino alkyl group, substituted or unsubstituted guanidyl group, wherein substituent groups on the substituted guanidyl group are chosen from C₁-C₂ alkyl on a nitrogen of the guanidyl group, and R′ and R independently can be a moiety having the formula:

H₂N—[—(CH₂)ₙ—NH-]ₘ—(CH₂)ₙ— (II)

wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups;
water;
optionally a chelating agent;
optionally a corrosion inhibitor;
optionally an oxidizing agent;
optionally a source of iron (III) ions;
optionally a surfactant;
optionally a defoaming agent;
optionally biocide; and
optionally a pH adjustor;
providing a chemical mechanical polishing pad, having a polishing surface; creating dynamic contact at an interface between the chemical mechanical polishing pad and the substrate; and dispensing the chemical mechanical polishing composition onto the polishing surface of the chemical mechanical polishing pad at or near the interface between the chemical mechanical polishing pad and the substrate; wherein at least some of the copper and the TEOS are polished away from the substrate.

The chemical mechanical polishing compositions of the present invention having modified silanized colloidal silica particles enable high removal rates of dielectric materials, such as TEOS, and metals such as copper, from substrates during chemical mechanical polishing. The silanized colloidal silica particles of the present invention can be tuned to control polishing performance by modifying the epoxysilane joined to the colloidal silica particles or by modifying the amine covalently bonded to the epoxysilane.

### DETAILED DESCRIPTION OF THE INVENTION

As used throughout this specification the following abbreviations have the following meanings, unless the context indicates otherwise: ° C.=degrees Centigrade; g=grams; mL=milliliters; kPa=kilopascal; A=angstroms; DI=deionized; ppm=parts per million; mol=mole; m=meter; mm=millimeters; nm=nanometers; min=minute; hr=hour; rpm=revolutions per minute; lbs=pounds; H=hydrogen; Cu=copper; Mn=manganese; Fe=iron; N=nitrogen; O=oxygen; Ta=tantalum; TaN=tantalum nitride; KOH=potassium hydroxide; HO=hydroxyl; BTA=benzotriazole; IPA=isopropyl alcohol; Si—OH=silanol group; IC=ion chromatography; wt=weight; wt %=percent by weight; BET=Bunauer-Emmett-Teller; RR=removal rate; and Ex=example.

The term “chemical mechanical polishing” or “CMP” refers to a process where a substrate is polished by means of chemical and mechanical forces alone and is distinguished from electrochemical-mechanical polishing (ECMP) where an electric bias is applied to the substrate. The terms “compositions”, “dispersions” and “slurries” are used interchangeably throughout the specification. The term “silane” and “epoxysilane” are used interchangeably throughout the specification. The term “functionality” means a moiety of a molecule which has a decisive influence on the molecules reactivity. The term “reaction product” as used throughout the specification means the final modified silanized colloidal silica particle. The term “TEOS” means the silicon dioxide formed from tetraethyl orthosilicate (Si(OC₂H₅)₄). The term “alkylene” means a bivalent saturated aliphatic group or moiety regarded as derived from an alkene by opening of the double bond, such as ethylene: —CH₂—CH₂—, or from an alkane by removal of two hydrogen atoms from different carbon atoms. The term “methylene group” means a methylene bridge or methanediyl group with a formula: —CH₂— where a carbon atom is bound to two hydrogen atoms and connected by single bonds to two other distinct atoms in the molecule. The term “alkyl” means an organic group with a general formula: CₙH₂ₙ₊₁ where “n” is an integer and the “yl” ending means a fragment of an alkane formed by removing a hydrogen. The term “moiety” means a part or a functional group of a molecule. The terms “a” and “an” refer to both the singular and the plural. All percentages are by weight, unless otherwise noted. All numerical ranges are inclusive and combinable in any order, except where it is logical that such numerical ranges are constrained to add up to 100%.

The present invention is directed to chemical mechanical polishing compositions containing silanized colloidal silica particles comprising (preferably, consisting of) a reaction product of an epoxy functionality of a silanized colloidal silica particle with a nitrogen of an amine. Epoxysilane compounds react with silanol groups on the surfaces of the colloidal silica particles to form covalent siloxane bonds (Si—O—Si) with the silanol groups or, alternatively, the epoxysilane compounds are linked to the silanol groups by, for example, hydrogen bonding. In the second step, the first reaction product which includes a free epoxy functionality is reacted with an amine compound in an addition reaction. A hydrogen atom is removed from a nitrogen atom of the amine and the nitrogen atom from the amine reacts with the epoxy functionality to form the final modified colloidal silica particle. Substantially all the amine reagents react with the epoxy functionalities to form a covalent bond.

The colloidal silanized silica particles of the present invention can be made, preferably, by making a 30-60% pre-hydrolyzed aqueous silane solution by mixing desirable amounts weight by weight of epoxysilane and DI water for about 0.5-2 hr. Silane surface modification is done by slowly adding the 30-60% pre-hydrolyzed aqueous epoxysilane solution into dispersions of colloidal silica particles over a period of about 1-10 min. DI water is then mixed with the silane modified colloidal silica particles to make dispersions. The dispersions can then be further aged at room temperature for at least 1 hr.

Amine solutions are then added to the silane modified colloidal silica particle dispersions with mixing at room temperature. The dispersions are aged at room temperature for about 1-10 days or at 50-60° C. for about 1-24 hr. The dispersions are then diluted with DI water and pH is adjusted with acid, such as inorganic acids chosen from nitric acid, hydrochloric acid, sulfuric acid or phosphoric acid, or an organic acid, to a pH in the range of 4-7, preferably, from 4.5-6.

The properties and performance of surface modified particles can depend on numbers of functional groups per surface area created by modification. Particles with different sizes or shapes have different specific surface areas, thus they require different amounts of epoxysilane and amine to achieve the same degree of functionalization. For this reason, degree of surface functionalization depends on both the amount of epoxysilane and amine added during the surface modification and total particle surface area available for surface reaction. For ease of comparison between particles with different specific surface area, the number of epoxysilane or amine molecules per nm² of surface area of particle is calculated from the amount of epoxysilane and amine added. This can be done using the following equation.

Ns=(Ws/Mw×NA)/(SSA×Wp×10¹⁸) Equation (1)

Ns: Number of epoxysilane or amine per nm² of surface area of particle in number of molecules/nm².
Ws: Weight of epoxysilane or amine added in grams.
Mw: Molecular weight, g/mol of epoxysilane or amine
NA: Avogadro's number, 6.022×10²³ mol⁻¹
SSA: Specific surface area of particle in m²/g
Wp: Total weight of particle in solution.
SSA can be obtained by BET surface area measurement or Sears titration (determination of specific surface area of colloidal silica by titration with sodium hydroxide, G. W. Sears, Anal. Chem. 1956, 28, 12, 1981-1983.), both processes are well known in the art.

Preferably, epoxysilane compounds are mixed and reacted with the colloidal silica particles in an aqueous environment to provide a molecule of epoxysilane compound on the surface of the particle of 0.05-1 molecules of silane per nm² of surface area, more preferably, from 0.1-0.8 molecules of silane per nm² of surface area, even more preferably, from 0.15-0.6 molecules of silane per nm² of surface area. If the epoxysilane is not readily water soluble, an alcohol such as IPA or other suitable alcohol can be used as a co-solvent to help solubilize the epoxysilane.

The weight ratio of epoxysilane/silica is in the range of about 0.0005 to 0.05, more preferably, from 0.001 to 0.025, even more preferably, from 0.002 to 0.02.

Preferably, amine compounds are included in amounts such that one molecule of the amine covers 0.05-1 molecules of amine per nm² of particle surface area, more preferably, from 0.1-0.8 molecules of amine per nm² of particle surface area. The amine is calculated by the same process as that of the epoxysilane.

The weight ratio of amine/silica is in the range of about 0.0001 to 0.05, more preferably, from 0.0002 to 0.02, even more preferably, from 0.0005 to 0.01.

Weight in grams of the epoxysilane or amine can be calculated using the following equation.

Ws=(Ns×SSA×Wp×10¹⁸/NA)×Mw Equation (2)

Ns: Number of epoxysilane or amine per nm² of surface area of particle in number of molecules/nm².
Ws: Weight of epoxysilane or amine added in grams.
Mw: Molecular weight, g/mol of epoxysilane or amine
NA: Avogadro's number, 6.022×10²³ mol⁻¹
SSA: Specific surface area of particle in m²/g
Wp: Total weight of particles in solution.

Epoxysilanes include, but are not limited to, 5,6-epoxyhexyltriethoxysilane, 2-(3,4-epoxycyclohexyl)ethyltrimethoxsilane, and glycidoxysilanes. Preferably, the epoxysilanes are glycidoxysilanes. Exemplary glycidoxysilane compounds are (3-glycidoxypropyl) trimethoxysilane, γ-glycidoxypropylmethyl diethoxysilane, γ-glycidoxypropyl trimethoxysilane and (3-glycidoxypropyl) hexyltrimethoxysilane.

Amines include amine compounds which have at least one hydrogen atom which can be removed from a nitrogen in an addition reaction to enable the nitrogen to react with the epoxy functionality of the epoxysilane. Such amines include amine compounds having a primary or secondary amine functionality. Preferably, the amine has a primary amine functionality.

Exemplary amines are ethanolamine, N-methylethanolamine, butylamine, dibutylamine, 3-ethoxypropylamine, ethylenediamine, N,N-dimethylethylenediamine, 3-(dimethylamino)-1-propylamine, 3-(diethylamino) propylamine, (2-aminoethyl) trimethylammonium chloride hydrochloride, triethylenetetramine, teraethylenepentamine, pentaethylenehexamine, guanidine, guanidine acetate and 1,1,3,3-tetramethylguanidine.

Preferably, the reaction products of the epoxy functionality of the silanized colloidal silica particle and the amines of the present invention are modified silanized colloidal silica particles having the general structure:

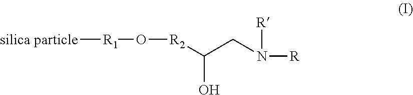

wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups of the substituted amino alkyl include linear or branched C₁-C₄ alkyl on the nitrogen of the amino alky group, substituted or unsubstituted guanidyl group, wherein substituent groups of the substituted guanidyl group are chosen from C₁-C₂ alkyl on an nitrogen of the guanidyl group, and R′ and R independently can be a moiety having the formula:

H₂N—[—(CH₂)ₙ—NH-]ₘ—(CH₂)ₙ— (II)

wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.

Preferably, R₁ and R₂ are independently chosen from linear C₁-C₅ alkylene groups, such as —(CH₂)ₜ— where t is an integer of 1-5, more preferably, R₁ is C₃ alkylene or propylene, such as —(CH₂)ₜ— where t=3 and R₂ is C₁ alkylene or methylene, such as —(CH₂)ₜ— where t=1. Preferably, R and R′ are independently chosen from hydrogen, hydroxy C₁-C₃ alky, linear or branched C₁-C₄ alkyl, alkoxy C₁-C₄ alkyl, substituted or unsubstituted amino C₁-C₄ alkyl, wherein when the nitrogen of the amino alkyl group is substituted, preferably, the nitrogen is substituted with one or two C₁-C₂ alkyl groups, and R′ and R independently can be a moiety having the formula:

H₂N—[—(CH₂)ₙ—NH-]ₘ—(CH₂)ₙ— (II)

wherein n and m are independently integers from 2-4. More preferably, R and R′ are independently chosen from hydrogen, hydroxy C₂-C₃ alkyl, unsubstituted amino C₂-C₃ alkyl, and R′ and R independently can be a moiety having the formula:

H₂N—[—(CH₂)ₙ—NH-]ₘ—(CH₂)ₙ— (II)

wherein n is 2 and m is an integer from 2-4.

More preferably, the reaction product of the epoxy functionality and the amine has the general structure:

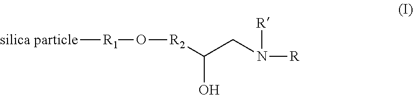

wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups on the substituted amino alkyl group include linear or branched C₁-C₄ alkyl on the nitrogen of the amino alkyl group, substituted or unsubstituted guanidyl group, wherein substituent groups of the substituted guanidyl group are chosen from C₁-C₂ alkyl on an nitrogen of the guanidyl group, and R′ and R independently can be a moiety having the formula:

H₂N—[—(CH₂)ₙ—NH-]ₘ—(CH₂)ₙ— (II)

wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.

More preferably, R₁ and R₂ are independently chosen from linear C₁-C₅ alkylene groups, such as —(CH₂)ₜ— where t is an integer of 1-5, more preferably, R₁ is C₃ alkylene or propylene, such as —(CH₂)ₜ— where t=3 and R₂ is C₁ alkylene or methylene, such as —(CH₂)ₜ— where t=1. Preferably, R and R′ are independently chosen from hydrogen, hydroxy C₁-C₃ alky, linear or branched C₁-C₄ alkyl, alkoxy C₁-C₄ alkyl, substituted or unsubstituted amino C₁-C₄ alkyl, wherein when the nitrogen of the amino alkyl is substituted, preferably, the nitrogen is substituted with one or two C₁-C₂ alkyl groups, and R′ and R independently can be a moiety having the formula:

H₂N—[—(CH₂)ₙ—NH-]ₘ—(CH₂)ₙ— (II)

wherein n and m are independently integers from 2-4. Even more preferably, R and R′ are independently chosen from hydrogen, hydroxy C₂-C₃ alkyl, unsubstituted amino C₂-C₃ alkyl, and a moiety having the formula:

H₂N—[—(CH₂)ₙ—NH-]ₘ—(CH₂)ₙ— (II)

wherein n is 2 and m is an integer from 2-4.

The modified silanized colloidal silica abrasive particles are included in the chemical mechanical polishing compositions of the present invention in amounts of greater than 0 wt % but not more than 5 wt %, preferably, greater than 0 wt % but not more than 4 wt %, more preferably, greater than 0 wt % but not more than 3 wt %, even more preferably, 1-3 wt %, most preferable, 1-2 wt % of the chemical mechanical polishing composition.

Preferably, the modified silanized colloidal silica particles of the present invention have an average diameter ranging from 5 nm to 200 nm, more preferably, from 10 nm to 100 nm, even more preferably, from 20 nm to 80 nm, as measured by dynamic light (DL) scattering techniques. Suitable particle size measuring instruments are available from, for example, Malvern Instruments (Malvern, UK).

Colloidal silica particles used to prepare the modified silanized colloidal silica particles of the present invention can be spherical, nodular, bent, elongated or cocoon shaped colloidal silica particles. Preferably, the surface area of the colloidal silica particles is 20 m²/g and greater, more preferably, from 20 m²/g to 200 m²/g, most preferably, from 30 m²/g to 150 m²/g. Such colloidal silica particles are commercially available. Examples of commercially available colloidal silica particles are Fuso BS-3 and Fuso SH-3 both available from Fuso Chemical Co., LTD.

Water is also included in the chemical mechanical polishing compositions of the present invention. Preferably, the water contained in the chemical mechanical polishing compositions is at least one of deionized and distilled to limit incidental impurities.

Optionally, the chemical mechanical polishing compositions of the present invention can include one or more corrosion inhibitors. Conventional corrosion inhibitors can be used. Corrosion inhibitors include, but are not limited to, benzotriazole; 1,2,3-benzotriazole; 1,6-dimethyl-1,2,3-benzotriazole; 1-(1,2-dicarboxyethyl)benzotriazole; 1-[N,N-bis(hydroxylethyl)aminomethyl]benzotrizole; or 1-(hydroxylmethyl)benzotriazole.

Corrosion inhibitors can be included in the chemical mechanical polishing composition in conventional amounts. Preferably, corrosion inhibitors are included in amounts of 0.01-1 wt %, more preferably, from 0.01-0.5 wt %, even more preferably, from 0.01-0.1 wt % of the chemical mechanical polishing composition.

Optionally, one or more chelating agents can be included in the chemical mechanical polishing compositions of the present invention. Preferably, the chelating agents are amino acids and carboxylic acids. Such amino acids include, but are not limited to, alanine, arginine, aspartic acid, cysteine, glutamine, glutamic acid, glycine, histidine, isoleucine, leucine, lysine methionine, phenylalanine, proline, serine, threonine, tryptophan, tyrosine, valine and mixtures thereof. Preferably, the amino acids are selected from the group consisting of aspartic acid, alanine, arginine, glutamine, glycine, leucine, lysine, serine and mixtures thereof, more preferably, the amino acids are selected from the group consisting of aspartic acid, alanine, glutamine, glycine, lysine, serine and mixtures thereof, even more preferably, the amino acids are selected from the group consisting of aspartic acid, alanine, glycine, serine and mixtures thereof, most preferably, the amino acid is aspartic acid. Carboxylic acids include, but are not limited to, malic acid, malonic acid, tartaric acid, citric acid, oxalic acid, gluconic acid, lactic acid.

Chelating agents can be included in the chemical mechanical polishing composition, as an initial component, from 0.001 wt % to 1 wt %, more preferably, from 0.005 wt % to 0.5 wt %, even more preferably, from 0.005 wt % to 0.1 wt %, most preferably from, 0.02 wt % to 0.1 wt %.

Optionally, the chemical mechanical polishing compositions of the present invention include one or more oxidizing agents, wherein the oxidizing agents are selected from the group consisting of hydrogen peroxide (H₂O₂), monopersulfates, iodates, magnesium perphthalate, peracetic acid and other per-acids, persulfate, bromates, perbromate, persulfate, peracetic acid, periodate, nitrates, iron salts, cerium salts, Mn (III), Mn (IV) and Mn (VI) salts, silver salts, copper salts, chromium salts, cobalt salts, halogens, hypochlorites and a mixture thereof. Preferably, the oxidizing agent is selected from the group consisting of hydrogen peroxide, perchlorate, perbromate, periodate, persulfate and peracetic acid. Most preferably, the oxidizing agent is hydrogen peroxide.

The chemical mechanical polishing composition can contain 0.01-10 wt %, preferably, 0.1-5 wt %; more preferably, 0.1-1 wt % of an oxidizing agent.

Optionally, the chemical mechanical polishing compositions of the present invention can include a source of iron (III) ions, wherein the source of iron (III) ions is selected from the group consisting iron (III) salts. Most preferably the chemical mechanical polishing composition contains a source of iron (III) ions, wherein the source of iron (III) ions is ferric nitrate nonahydrate, (Fe(NO₃)₃.9H₂O).

The chemical mechanical polishing composition can contain a source of iron (III) ions sufficient to introduce 1 to 200 ppm, preferably, 5 to 150 ppm, more preferably, 7.5 to 125 ppm, most preferably, 10 to 100 ppm of iron (III) ions to the chemical mechanical polishing composition. In a particularly preferred chemical mechanical polishing composition the source of iron (III) ions is included in amounts sufficient to introduce 10 to 150 ppm to the chemical mechanical polishing composition.

Optionally, the chemical mechanical polishing composition contains a pH adjusting agent. Preferably, the pH adjusting agent is selected from the group consisting of inorganic and organic pH adjusting agents. Preferred organic acids are chosen from one or more amino acids. More preferably, the pH adjusting agent is selected from the group consisting of inorganic acids and inorganic bases. Inorganic acids include, but are not limited to, nitric acid, sulfuric acid, hydrochloric acid and phosphoric acid. Inorganic bases include, but are not limited to, potassium hydroxide, sodium hydroxide and ammonium hydroxide. Further preferably, the pH adjusting agent is selected from the group consisting of nitric acid and potassium hydroxide. Most preferably, the pH adjusting agent is nitric acid. Sufficient amounts of the pH adjusting agent are added to the chemical mechanical polishing composition to maintain a desired pH or pH range of 4-7, preferably, from 4.5-6.

Optionally, the chemical mechanical polishing composition contains biocides, such as KORDEK™ MLX (9.5-9.9% methyl-4-isothiazolin-3-one, 89.1-89.5% water and ≤1.0% related reaction product) or KATHON™ ICP III containing active ingredients of 2-methyl-4-isothiazolin-3-one and 5-chloro-2-methyl-4-isothiazolin-3-one, each manufactured by International Flavors & Fragrances, Inc., (KATHON and KORDEK are trademarks of International Flavors & Fragrances, Inc.).

When biocides are included in the chemical mechanical polishing composition of the present invention, the biocides are included in amounts of 0.001 wt % to 0.1 wt %, preferably, 0.001 wt % to 0.05 wt %, more preferably, 0.001 wt % to 0.01 wt %, still more preferably, 0.001 wt % to 0.005 wt %.

Optionally, the chemical mechanical polishing composition can further include surfactants. Conventional surfactants can be used in the chemical mechanical polishing compositions. Such surfactants include, but are not limited to, non-ionic surfactants, anionic surfactants, cationic surfactants, amphoteric surfactants. Mixtures of such surfactants can also be used in the chemical mechanical polishing compositions of the present invention. Minor experimentation can be used to determine the type or combination of surfactants to achieve the desired viscosity of the chemical mechanical polishing composition.

Optionally, the chemical mechanical polishing compositions of the present invention can also include defoaming agents, such as non-ionic surfactants including esters, ethylene oxides, alcohols, ethoxylate, silicon compounds, fluorine compounds, ethers, glycosides and their derivatives. Anionic ether sulfates such as sodium lauryl ether sulfate (SLES) as well as the potassium and ammonium salts.

Surfactants and defoaming agents can be included in the chemical mechanical polishing compositions of the present invention in conventional amounts or in amounts tailored to provide the desired performance. For example, the chemical mechanical polishing composition can contain 0.0001 wt % to 0.1 wt %, preferably, 0.001 wt % to 0.05 wt %, more preferably, 0.01 wt % to 0.05 wt %, still more preferably, 0.01 wt % to 0.025 wt %, of a surfactant, defoaming agent or mixtures thereof.

The chemical mechanical polishing compositions can be used to polish various substrates. The modified silanized colloidal silica abrasive particles of the present invention are tunable for a given substrate or material, such as a dielectric and a metal. Such dielectric materials include, but are not limited to, TEOS and low-K film (low dielectric film). Metals include, but are not limited to copper, Ta and TaN. By changing the epoxysilane or the amine or a combination of the epoxysilane and amine of the modified silanized colloidal silica particle. Minor experimentation can be done to determine which combination of epoxysilanes and amines can achieve the desired polishing performance for a given metal or dielectric.

Preferably, the modified silanized colloidal silica abrasives of the present invention are included in chemical mechanical polishing compositions to preferably polish TEOS and copper.

The polishing method of the present invention includes providing a chemical mechanical polishing pad, having a polishing surface; creating dynamic contact at an interface between the chemical mechanical polishing pad and the substrate; and dispensing the chemical mechanical polishing composition of the present invention onto the polishing surface of the chemical mechanical polishing pad at or near the interface between the chemical mechanical polishing pad and the substrate; wherein at least some dielectric material is polished away from the substrate.

Preferably, in the method of polishing a substrate with the chemical mechanical polishing composition of the present invention, the substrate comprises copper and TEOS. Most preferably, the substrate provided is a semiconductor substrate comprising copper deposited within at least one of holes and trenches formed in a dielectric such as TEOS.

Preferably, in the method of polishing a substrate of the present invention, the chemical mechanical polishing pad provided can by any suitable polishing pad known in the art. One of ordinary skill in the art knows to select an appropriate chemical mechanical polishing pad for use in the method of the present invention. More preferably, in the method of polishing a substrate of the present invention, the chemical mechanical polishing pad provided is selected from woven and non-woven polishing pads. Still more preferably, in the method of polishing a substrate of the present invention, the chemical mechanical polishing pad provided comprises a polyurethane polishing layer. Most preferably, in the method of polishing a substrate of the present invention, the chemical mechanical polishing pad provided comprises a polyurethane polishing layer containing polymeric hollow core microparticles and a polyurethane impregnated non-woven subpad. Preferably, the chemical mechanical polishing pad provided has at least one groove on the polishing surface.

Preferably, in the method of polishing a substrate of the present invention, the chemical mechanical polishing composition provided is dispensed onto a polishing surface of the chemical mechanical polishing pad provided at or near an interface between the chemical mechanical polishing pad and the substrate.

Preferably, in the method of polishing a substrate of the present invention, dynamic contact is created at the interface between the chemical mechanical polishing pad provided and the substrate with a down force of 0.69 to 34.5 kPa normal to a surface of the substrate being polished.

Preferably, in the method of polishing a substrate of the present invention, the chemical mechanical polishing composition of the present invention has a TEOS removal rate ≥400 Å/min; preferably, ≥500 Å/min; more preferably, ≥600 Å/min. Preferably, in the method of polishing a substrate of the present invention, the chemical mechanical polishing composition has a copper removal rate of ≥250 Å/min; preferably, ≥400 Å/min; more preferably, ≥600 Å/min. Preferably, polishing is done with a platen speed of 93 revolutions per minute, a carrier speed of 87 revolutions per minute, a chemical mechanical polishing composition flow rate of 200 mL/min, a nominal down force of 27.6 kPa on a 200 mm or 300 mm polishing machine; and, wherein the chemical mechanical polishing pad comprises a polyurethane polishing layer containing polymeric hollow core microparticles and a polyurethane impregnated non-woven subpad.

The following examples are intended to further illustrate the present invention but are not intended to limit its scope.

### Example 1

### Chemical Mechanical Polishing TEOS and Copper

50% by weight pre-hydrolyzed aqueous silane solutions were prepared by mixing equal weights of silane and DI water for 1 hr. For each slurry silane surface modification was done by slowly adding the desired amount of the 50% pre-hydrolyzed aqueous silane solutions containing GPTMS into dispersions of Fuso BS-3 particles over a period of 5 min. DI water was then mixed with the silane modified Fuso BS-3 colloidal silica particles to make 18% by weight dispersions of the particles. The dispersions were then further aged at room temperature for 30 min to 1 hr before adding amines. Ex1-1 included 0.0367 wt % GPTMS. Ex1-2 to Ex1-11 included 0.0275 wt % GPTMS.

Aqueous amine solutions containing ethylenediamine were added into the above prepared particle dispersions with mixing. Ex1-1 included 0.0078 wt % EDA. Ex1-2 to Ex1-9 included 0.0054 wt % EDA. Ex1-10 included 0.0062 wt % EDA and Ex1-11 included 0.0070 wt % EDA. The dispersions were aged at 55° C. for 24 hr. The dispersions of modified particles were then diluted with DI water and benzotriazole was added in amounts of 0.02% by weight. The final modified particle concentration in the slurries was 2% by weight. Hydrogen peroxide in amounts of 0.4 weight % was added to each polishing composition just prior to polishing. The final pH was adjusted with aspartic acid and potassium hydroxide. The final pH values are in Table 1 below.

The unit of the amount of silane and amine listed in the table is number of molecules per nm² based on surface area of the Fuso BS-3 silica particles which was 78 m²/g as provided by FUSO Chemical Co., Ltd. The molecules per nm² for the silane and amine were determined using the following equation:

Ns=(Ws/Mw×NA)/(SSA×Wp×10¹⁸)

Ns: Number of GPTMS or EDA per nm² surface area of particle in number of molecules/nm²,
NA: Avogadro's number, 6.022×10²³ mol⁻¹,
Mw of GPTMS=236.34 g/mol,
Mw of EDA=60.1 g/mol,
SSA=78 m²/g,

### Wp=2 wt %,

Ws=Weight of epoxysilane or amine added in grams.

TABLE 1

| | GPTMS/ | EDA/ | Aspartic | | TEOS RR, | Cu RR, |
|---|---|---|---|---|---|---|
| Example | nm² | nm² | acid wt % | pH | Å/min | Å/min |
| Comparative | 0 | 0 | 0.1 | 5.80 | 96 | 517 |
| Ex-1C | | | | | | |
| Ex1-1 | 0.6 | 0.5 | 0.2 | 5.32 | 715 | 1170 |
| Ex1-2 | 0.45 | 0.35 | 0.2 | 5.30 | 775 | 1279 |
| Ex1-3 | 0.45 | 0.35 | 0.1 | 4.80 | 681 | 893 |
| Ex1-4 | 0.45 | 0.35 | 0.1 | 5.31 | 821 | — |
| Ex1-5 | 0.45 | 0.35 | 0.1 | 5.83 | 780 | 682 |
| Ex1-6 | 0.45 | 0.35 | 0.1 | 6.32 | 687 | 573 |
| Ex1-7 | 0.45 | 0.35 | 0.02 | 5.80 | 749 | 356 |
| Ex1-8 | 0.45 | 0.35 | 0.05 | 5.82 | 752 | 520 |
| Ex1-9 | 0.45 | 0.35 | 0.2 | 5.83 | 697 | 962 |
| Ex1-10 | 0.45 | 0.40 | 0.1 | 5.84 | 664 | 619 |
| Ex1-11 | 0.45 | 0.45 | 0.1 | 5.85 | 715 | 751 |

GPTMS: 3-glycidoxypropyltrimethoxysilane;
EDA: Ethylenediamine

The removal rates were obtained by polishing TEOS wafers (supplied by Pure Wafer) and copper wafers (supplied by Skorpios) using Applied Materials Mirrar™ 200 mm polishing machine with Fujibo H800 pad at down-forces of 10.3 kPas, a platen/carrier speed of 93/87 rpm, and a slurry flow rate of 200 mL/min. The polishing pad was conditioned using 3M A82 for 6 seconds ex-situ at 3 lbs down force.

The polishing data showed that TEOS and copper removal rates of the inventive chemical mechanical polishing compositions were significantly higher than the non-inventive composition Comparative Ex-1C except for Ex-7 which had a lower copper RR.

### Example 2

Chemical Mechanical Polishing TEOS and Copper with Different Particle Types A plurality of chemical mechanical polishing slurry compositions was prepared as described in Example 1 above except two different types of silica particles were used in different amounts at low particle concentrations below 5% by weight as shown in Table 2b. The amount of GPTMS by weight % and amount of EDA by weight % in each example are listed in table 2a below.

TABLE 2a

| Example | GPTMS (wt %) | EPA (wt %) |
|---|---|---|
| Ex2-1 | 0.0275 | 0.0054 |
| Ex2-2 | 0.0069 | 0.0014 |
| Ex2-3 | 0.0138 | 0.0027 |
| Ex2-4 | 0.0206 | 0.0041 |
| Ex2-5 | 0.0413 | 0.0082 |
| Ex2-6 | 0.0551 | 0.0109 |
| Ex2-7 | 0.0184 | 0.0039 |
| Ex2-8 | 0.0367 | 0.0078 |
| Ex2-9 | 0.0551 | 0.0117 |
| Ex2-10 | 0.0275 | 0.0054 |
| Ex2-11 | 0.0275 | 0.0070 |
| Ex2-12 | 0.0367 | 0.0078 |
| Ex2-13 | 0.0367 | 0.0093 |

Benzotriazole and hydrogen peroxide were added to the polishing compositions containing the modified particles in the amounts disclosed in Example 1 above. Particle size was measured using Malvern Zetasizer Nano ZS without further dilution.

The unit of the amount of silane and amine listed in the table is number of molecules per nm² based on surface area of silica particles of both Fuso BS-3 and SH-3 being 78 m²/g. The values were calculated using the equation as shown in Example 1.

The removal rates were obtained by polishing TEOS and copper wafers using Applied Materials Mirra™ 200 mm polishing machine with Fujibo H800 pad at down-forces of 10.3 kPas, a platen/carrier speed of 93/87 rpm, and a slurry flow rate of 200 mL/min. The polishing pad was conditioned using 3M A82 for 6 seconds ex-situ at 3 lbs down force.

TABLE 2b

| | Particle | Particle | GPTMS/ | EDA/ | | Size-DLS | TEOS RR | Cu RR |
|---|---|---|---|---|---|---|---|---|
| Example | type | wt % | nm² | nm² | pH | (nm) | (Å/min) | (Å/min) |
| Comparative | SH-3 | 2 | | | 5.84 | 80 | 91 | 563 |
| Ex2C | | | | | | | | |
| Ex2-1 | BS-3 | 2 | 0.45 | 0.35 | 5.84 | 71 | 736 | 772 |
| Ex2-2 | BS-3 | 0.5 | 0.45 | 0.35 | 5.81 | 73 | 394 | 454 |
| Ex2-3 | BS-3 | 1 | 0.45 | 0.35 | 5.84 | 74 | 588 | 579 |
| Ex2-4 | BS-3 | 1.5 | 0.45 | 0.35 | 5.83 | 72 | | 681 |
| Ex2-5 | BS-3 | 3 | 0.45 | 0.35 | 5.82 | 70 | 801 | 913 |
| Ex2-6 | BS-3 | 4 | 0.45 | 0.35 | 5.81 | 69 | 832 | 1036 |
| Ex2-7 | BS-3 | 1 | 0.60 | 0.50 | 5.83 | 73 | 544 | 617 |
| Ex2-8 | BS-3 | 2 | 0.60 | 0.50 | 5.80 | 71 | 656 | 816 |
| Ex2-9 | BS-3 | 3 | 0.60 | 0.50 | 5.82 | 73 | 714 | 968 |
| Ex2-10 | SH-3 | 2 | 0.45 | 0.35 | 5.83 | 81 | 489 | 813 |
| Ex2-11 | SH-3 | 2 | 0.45 | 0.45 | 5.84 | 79 | 483 | 900 |
| Ex2-12 | SH-3 | 2 | 0.60 | 0.50 | 5.85 | 79 | 453 | 901 |
| Ex2-13 | SH-3 | 2 | 0.60 | 0.60 | 5.82 | 81 | 446 | 975 |

GPTMS: 3-glycidoxypropyltrimethoxysilane;
EDA: Ethylenediamine

The polishing data showed that at the same particle concentration of 2% by weight of SH-3 particles TEOS removal rates of the inventive compositions were significantly higher than the non-inventive composition Comparative Ex2C.

Although the relationship between particle concentrations and TEOS RR is not a linear relationship, the polishing results showed that both TEOS and Cu RRs increased with the increased amounts of BS-3 particles from 0.5% by weight up to 4% by weight.

### Example 3

Chemical Mechanical Polishing of TEOS and Copper with Different Amines Slurry compositions were prepared and evaluated according to the procedures described in Example 1. The amount of GPTMS by weight %0 and type and amount of amine by weight % in each example are listed in table below.

TABLE 3a

| Example | GPTMS (wt %) | Amine | Amine (wt %) |
|---|---|---|---|
| Ex3-1 | 0.0275 | EDA | 0.0056 |
| Ex3-2 | 0.0184 | EDA | 0.0037 |
| Ex3-3 | 0.0275 | TETA | 0.0136 |
| Ex3-4 | 0.0184 | TETA | 0.0091 |
| Ex3-5 | 0.0184 | TEPA | 0.118 |
| Ex3-6 | 0.0275 | PEHA | 0.0217 |
| Ex3-7 | 0.0184 | PEHA | 0.0144 |
| Comparative Ex3A | 0.275 | 0 | 0 |
| Comparative Ex3B | 0 | EDA | 0.0056 |
| Comparative Ex3C | 0 | 0 | 0 |

The unit of the amount of silane and amine listed in the table is number of molecules per nm² based on surface area of silica particle being 78 m²/g as calculated by the equation disclosed in Example 1.

Each polishing composition containing the modified particles also included 0.06 by weight aspartic acid, 0.0200 by weight benzotriazole and 0.400 by weight hydrogen peroxide. The pH of the slurry compositions was adjusted with an aqueous solution of KOH to 5.8. The hydrogen peroxide was added to the polishing composition immediately before polishing. The type and amount of particle in each composition is also listed in Table 3b.

The removal rates were obtained by polishing TEOS and Cu wafers using Applied Materials Mirra™ 200 mm polishing machine with Fujibo H800 pad at down-forces of 10.3 kPas, a platen/carrier speed of 93/87 rpm and a slurry flow rate of 200 mL/min. The polishing pad was conditioned using 3M A82 for 6 seconds ex-situ at 3 lbs down force.

TABLE 3b

| | Particle | Particle | GPTMS/ | | Amine/ | TEOS RR | Cu RR |
|---|---|---|---|---|---|---|---|
| Example | type | wt % | nm² | Amine | nm² | (Å/min) | (Å/min) |
| Ex3-1 | BS-3 | 2 | 0.45 | EDA | 0.36 | 763 | 549 |
| Ex3-2 | BS-3 | 2 | 0.30 | EDA | 0.24 | 741 | 512 |
| Ex3-3 | BS-3 | 2 | 0.45 | TETA | 0.36 | 668 | 589 |
| Ex3-4 | BS-3 | 2 | 0.30 | TETA | 0.24 | 715 | 577 |
| Ex3-5 | BS-3 | 2 | 0.30 | TEPA | 0.24 | 401 | 702 |
| Ex3-6 | BS-3 | 2 | 0.45 | PEHA | 0.36 | 37 | 508 |
| Ex3-7 | BS-3 | 2 | 0.30 | PEHA | 0.24 | 88 | 523 |
| Comparative | BS-3 | 2 | 0.45 | | | 48 | 439 |
| Ex3A | | | | | | | |
| Comparative | BS-3 | 2 | | EDA | 0.36 | 100 | 898 |
| Ex3B | | | | | | | |
| Comparative | BS-3 | 2 | | | | 64 | 426 |
| Ex3C | | | | | | | |

GPTMS 3-glycidoxypropyltrimethoxysilane
EDA Ethylenediamine
TETA Triethylenetetramine
TEPA Tetraethylenepentamine
PEHA Pentaethylenehexamine

Polishing data showed that TEOS removal rates of the inventive compositions were significantly higher than those of non-inventive compositions. When the amine functionality (number of amine groups in each molecule) is equal to 5 or less, the slurry compositions had high TEOS removal rates. When the amine functionality was equal to 6, TEOS removal rates were reduced, however, copper removal rates were still high.

### Example 4

Chemical Mechanical Polishing of TEOS and Copper with Different Amines Slurry compositions were prepared and evaluated according to the procedures described in Example 1. The amount of GPTMS by weight % and type and amount of amine by weight % in each example are listed in table below.

TABLE 4a

| Example | GPTMS (wt %) | Amine | Amine (wt %) |
|---|---|---|---|
| Comparative Ex4C | 0 | 0 | 0 |
| Ex4-1 | 0.0275 | EDA | 0.0056 |
| Ex4-2 | 0.0275 | DMEDA | 0.0082 |
| Ex4-3 | 0.0275 | DMAPA | 0.0095 |
| Ex4-4 | 0.0275 | DEAPA | 0.0121 |

The type and amount of particle in each composition is listed in Table 4b. The unit of the amount of silane and amine listed in the table is number of molecules per nm² based on surface area of silica particle being 78 m²/g.

Each polishing composition containing the modified particles also included 0.06% by weight aspartic acid, 0.02% by weight benzotriazole, 0.005% by weight KORDEK™ biocide and 0.4% by weight hydrogen peroxide. The pH of the slurries was adjusted with an aqueous solution of KOH to 5.8. The hydrogen peroxide was added to the polishing compositions immediately before polishing.

The removal rates were obtained by polishing TEOS and Cu wafers using Applied Materials Mirra™ 200 mm polishing machine with Fujibo H800 pad at down-forces of 10.3 kPas, a platen/carrier speed of 93/87 rpm and a slurry flow rate of 200 mL/min. The polishing pad was conditioned using 3M A82 for 6 seconds ex-situ at 3 lbs down force.

TABLE 4b

| | Particle | Particle | GPTMS/ | | Amine/ | TEOS RR | Cu RR |
|---|---|---|---|---|---|---|---|
| Example | type | (wt %) | nm² | Amine | nm² | (Å/min) | (Å/min) |
| Comparative | BS-3 | 2 | 0 | 0 | 0 | 64 | 426 |
| Ex4C | | | | | | | |
| Ex4-1 | BS-3 | 2 | 0.45 | EDA | 0.36 | 707 | 535 |
| Ex4-2 | BS-3 | 2 | 0.45 | DMEDA | 0.36 | 663 | 488 |
| Ex4-3 | BS-3 | 2 | 0.45 | DMAPA | 0.36 | 635 | 454 |
| Ex4-4 | BS-3 | 2 | 0.45 | DEAPA | 0.36 | 606 | 433 |

GPTMS 3-glycidoxypropyltrimethoxysilane
EDA Ethylenediamine
DMEDA N,N-Dimethylethylenediamine
DMAPA Dimethylaminopropylamine
DEAPA 3-(Diethylamino)propylamine

The polishing data showed that the inventive compositions had high TEOS and Cu removal rates.

### Example 5

### Chemical Mechanical Polishing of TEOS and Copper with Different Silica Particles

Slurry compositions were prepared according to the procedures as described in Example 1.

TABLE 5a

| | | | Specific | | |
|---|---|---|---|---|---|
| | Particle | Particle | Surface Area | GPTMS | EDA |
| Example | Supplier | Type | (m²/g) | (wt %) | (wt %) |
| Ex5-1 | Fuso | BS-3 | 78 | 0.0275 | 0.0070 |
| Comp Ex5A | Fuso | BS-3 | 78 | 0 | 0 |
| Ex5-2 | Fuso | HL-3 | 78 | 0.0275 | 0.0070 |
| Comp Ex5B | Fuso | HL-3 | 78 | 0 | 0 |
| Ex5-3 | Fuso | PL-3 | 78 | 0.0275 | 0.0070 |
| Comparative | Fuso | PL-3 | 78 | 0 | 0 |
| Ex5C | | | | | |
| Ex5-4 | Fuso | PL-2L | 109 | 0.0385 | 0.0098 |
| Ex5-5 | Fuso | BS-3 + PL-2L | 86 | 0.0303 | 0.0077 |
| Ex5-6 | Fuso | BS-2 | 109 | 0.0385 | 0.0098 |
| Ex5-7 | EMD | K1858 | 136 | 0.0482 | 0.0123 |
| Comparative | EMD | K1858 | 136 | 0 | 0 |
| Ex5D | | | | | |
| Ex5-8 | EMD | K1498-B50 | 50 | 0.0177 | 0.0045 |
| Comparative | EMD | K1498-B50 | 50 | 0 | 0 |
| Ex5E | | | | | |
| Ex5-9 | EMD | K1598-B25 | 109 | 0.0385 | 0.0098 |

Particle concentration of each composition was 20% by weight. The unit of the amount of silane and amine listed in table 5b is the number of molecules per nm² based on surface area of silica particles listed in table 5a above. The molecules of silane and amine were determined using the equation and procedure described in Example 1 above.

Each composition containing the modified particles also included 0.060% by weight aspartic acid, 0.0200 by weight benzotriazole, 0.005% by weight KORDEK™ biocide and 0.400 by weight hydrogen peroxide. The pH of the slurries was adjusted with aqueous potassium hydroxide to 5.8. The hydrogen peroxide was added to the polishing slurry immediately before polishing.

Both ultra-high purity colloidal silica particles (Fuso) and traditional water glass based colloidal silica particles were used (EMD). Ultra-high purity colloidal silica particles were prepared by hydrolysis of silicon alkoxide supplied by Fuso. Water glass based colloidal silica particles were manufactured by neutralizing silicate salt through ion exchange supplied by EMD under the tradename Klebosol® colloidal silica. Example Ex5-5 contained a mixture of Fuso BS-3 and Fuso PL-2L at a weight ratio 3:1. Particle size was measured using Malvern Zetasizer Nano ZS without further dilution.

The polishing of TEOS and Cu wafers was done using Applied Materials Mirra™ 200 mm polishing machine with Fujibo H800 pad at down-forces of 10.3 kPas, a platen/carrier speed of 93/87 rpm, and a slurry flow rate of 200 mL/min. The polishing pad was conditioned using 3M A82 for 6 seconds ex-situ at 3 lbs down force.

TABLE 5b

| | Particle | Particle | GPTMS/ | EDA/ | Size-DLS | TEOS RR | Cu RR |
|---|---|---|---|---|---|---|---|
| Example | Supplier | type | nm² | nm² | (nm) | (Å/min) | (Å/min) |
| Ex5-1 | Fuso | BS-3 | 0.45 | 0.45 | 67 | 738 | 644 |
| Comp Ex5A | Fuso | BS-3 | | | 80 | 89 | 352 |
| Ex5-2 | Fuso | HL-3 | 0.45 | 0.45 | 72 | 679 | 614 |
| Comp Ex5B | Fuso | HL-3 | | | 93 | 103 | 388 |
| Ex5-3 | Fuso | PL-3 | 0.45 | 0.45 | 71 | 437 | 593 |
| Comparative | Fuso | PL-3 | | | 71 | 82 | 405 |
| Ex5C | | | | | | | |
| Ex5-4 | Fuso | PL-2L | 0.45 | 0.45 | 28 | 416 | 506 |
| Ex5-5 | Fuso | BS-3 + | 0.45 | 0.45 | 65 | 616 | 555 |
| | | PL-2L | | | | | |
| Ex5-6 | Fuso | BS-2 | 0.45 | 0.45 | 52 | 652 | 584 |
| Ex5-7 | EMD | K1858 | 0.45 | 0.45 | 41 | 571 | 408 |
| Comparative | EMD | K1858 | | | 104 | 71 | 465 |
| Ex5D | | | | | | | |
| Ex5-8 | EMD | K1498-B50 | 0.45 | 0.45 | 79 | 282 | 572 |
| Comparative | EMD | K1498-B50 | | | 79 | 84 | 416 |
| Ex5E | | | | | | | |
| Ex5-9 | EMD | K1598-B25 | 0.45 | 0.45 | 44 | 245 | 332 |

GPTMS 3-glycidoxypropyltrimethoxysilane
EDA Ethylenediamine

The data showed that the comparative slurry compositions which contained unmodified particles had low TEOS removal rates, while the slurry compositions of the invention which contained modified particles all had higher TEOS removal rates regardless of particle type. Copper removal rates for the slurry compositions of the invention were also higher than the comparative slurries except Ex5-9.

In addition, the modified particles of the slurry compositions of the present invention were more stable than the non-modified particles of the comparative slurries as shown by the average particle sizes. The larger particles indicated more agglomeration than the smaller particles.

### Example 6

### Chemical Mechanical Polishing with Modified Colloidal Silica Particles Prepared with Three Different Epoxysilanes

50% by weight pre-hydrolyzed aqueous GPTMS silane solution was prepared by mixing equal amounts (wt/wt) of silane and DI water for 1 hr. ECHETMS and EHTEOS showed low water solubility, accordingly 25% by weight silane solutions were prepared by mixing water and isopropyl alcohol (IPA) at a ratio of 1:1:2 for 1 hr at room temperature.

The type and amount of silane by weight % and type and amount of amine by weight % in each example are listed in table 6a below.

TABLE 6a

| | | Silane Mw | Silane | | Amine Mw | Amine |
|---|---|---|---|---|---|---|
| Example | Silane | (g/mol) | (wt %) | Amine | (g/mol) | (wt %) |
| Ex6-1 | GPTMS | 236.3 | 0.0275 | EDA | 60.1 | 0.0070 |
| Ex6-2 | GPTMS | 236.3 | 0.0220 | EDA | 60.1 | 0.0056 |
| Ex6-3 | GPTMS | 236.3 | 0.0367 | EDA | 60.1 | 0.0093 |
| Ex6-4 | GPTMS | 236.3 | 0.0275 | DMEDA | 88.2 | 0.0103 |
| Ex6-5 | ECHETMS | 246.4 | 0.0230 | EDA | 60.1 | 0.0056 |
| Ex6-6 | ECHETMS | 246.4 | 0.0287 | EDA | 60.1 | 0.0070 |
| Ex6-7 | ECHETMS | 246.4 | 0.0383 | EDA | 60.1 | 0.0093 |
| Ex6-8 | ECHETMS | 246.4 | 0.0287 | DMEDA | 88.2 | 0.0103 |
| Ex6-9 | EHTEOS | 262.4 | 0.0245 | EDA | 60.1 | 0.0056 |
| Ex610 | EHTEOS | 262.4 | 0.0306 | EDA | 60.1 | 0.0070 |
| Ex6-11 | EHTEOS | 262.4 | 0.0408 | EDA | 60.1 | 0.0093 |
| Ex6-12 | EHTEOS | 262.4 | 0.0306 | DMEDA | 88.2 | 0.0103 |

Silane surface modification was done by slowly adding the pre-hydrolyzed aqueous silane solutions into aqueous colloidal silica particle dispersions over a period of 2 min. The mixture was then further aged at room temperature for 30 min to 1 hr before. DI water was mixed with the silanized colloidal silica particles to make the particle concentrations to be 15% by weight.

Amine solutions were then added into the above prepared particle dispersions with mixing at room temperature. After aging at 55° C. for 22 hrs, the dispersions were then diluted with DI water from 15% by weight to 2% by weight.

Each polishing composition included 2% by weight surface modified Fuso BS-3 colloidal silica particles, 0.05% by weight aspartic acid, 0.02% by weight BTA, 0.005% by weight KORDEK™ biocide and 0.4% by weight hydrogen peroxide. Hydrogen peroxide was added immediately before polishing. Final pH of the slurries was adjusted with KOH to 5.8.

Polishing of TEOS (Supplied by Pure Wafer), Cu (Supplied by Skorpios) and TaN (Supplied by Wafernet) wafers was done using Applied Materials Mirra™ 200 mm polishing machine with Fujibo H800 pad at down-forces of 10.3 kPas, a platen/carrier speed of 93/87 rpm, and a slurry flow rate of 200 mL/min. The polishing pad was conditioned using 3M A82 for 6 seconds ex-situ at 3 lbs down force.

TEOS, Cu and TaN polishing removal rates were listed in the table 6b. Polishing data for TaN using the comparative polishing slurry was not obtained.

TABLE 6b

| | | Silane/ | | Amine/ | TEOS RR, | Cu RR, | TaN RR, |
|---|---|---|---|---|---|---|---|
| Example | Silane | nm² | Amine | nm² | (Å/min) | (Å/min) | (Å/min) |
| Comparative | | | | | 89 | 352 | — |
| Ex6C | | | | | | | |
| Ex6-1 | GPTMS | 0.45 | EDA | 0.45 | 801 | 559 | 379 |
| Ex6-2 | GPTMS | 0.36 | EDA | 0.36 | 797 | 499 | 397 |
| Ex6-3 | GPTMS | 0.6 | EDA | 0.6 | 760 | 550 | 346 |
| Ex6-4 | GPTMS | 0.45 | DMEDA | 0.45 | 771 | 452 | 275 |
| Ex6-5 | ECHETMS | 0.36 | EDA | 0.36 | 745 | 524 | 419 |
| Ex6-6 | ECHETMS | 0.45 | EDA | 0.45 | 773 | 554 | 405 |
| Ex6-7 | ECHETMS | 0.6 | EDA | 0.6 | 757 | 550 | 353 |
| Ex6-8 | ECHETMS | 0.45 | DMEDA | 0.45 | 752 | 474 | 258 |
| Ex6-9 | EHTEOS | 0.36 | EDA | 0.36 | 784 | 529 | 415 |
| Ex610 | EHTEOS | 0.45 | EDA | 0.45 | 758 | 524 | 416 |
| Ex6-11 | EHTEOS | 0.6 | EDA | 0.6 | 742 | 555 | 357 |
| Ex6-12 | EHTEOS | 0.45 | DMEDA | 0.45 | 734 | 443 | 263 |

GPTMS 3-glycidoxypropyltrimethoxysilane
ECHETMS 2-(3,4-epoxycyclohexyl)ethyltrimethoxysilane
EHTEOS 5,6-epoxyhexyltriethoxysilane
EDA Ethylenediamine
DMEDA N,N-Dimethylethylenediamine

The polishing data showed that the chemical mechanical polishing compositions with the modified colloidal silica particles had high removal rates for each substrate: TEOS, Cu and TaN. The comparative Ex6C had substantially lower RR for TEOS and Cu.

What is claimed is:

1. A chemical mechanical polishing composition comprising a silanized colloidal silica particle comprising a reaction product of an epoxy functionality of the silanized colloidal silica particle with a nitrogen of an amine;
water;
optionally a chelating agent;
optionally a corrosion inhibitor;
optionally an oxidizing agent;
optionally a source of iron (III) ions;
optionally a surfactant;
optionally a defoaming agent;
optionally biocide; and
optionally a pH adjustor.

2. The silanized colloidal silica particle of claim 1, wherein the amine is selected from the group consisting of ethanolamine, N-methylethanolamine, butylamine, dibutylamine, 3-ethoxypropylamine, ethylenediamine, N,N-dimethylethylenediamine, 3-(dimethylamino)-1-propylamine, 3-(diethylamino) propylamine, (2-aminoethyl) trimethylammonium chloride hydrochloride, triethylenetetramine, teraethylenepentamine, pentaethylenehexamine, guanidine, guanidine acetate and 1,1,3,3-tetramethylguanidine.

3. The chemical mechanical polishing compositions of claim 1, wherein the silanized colloidal silica particle has the structure: 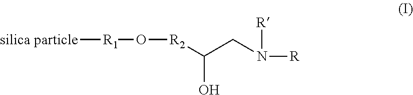
wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups on a nitrogen of the amino C₁-C₄ alkyl group include linear or branched C₁-C₄ alkyl, substituted or unsubstituted guanidyl group, wherein substituent groups on the substituted guanidyl group are chosen from C₁-C₂ alkyl on a nitrogen of the guanidyl group, and R′ and R independently can be a moiety having the formula:
H₂N—[—(CH₂)ₙ—NH—]ₘ—(CH₂)ₙ— (II)
wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.

4. A chemical mechanical polishing method comprising: providing a substrate comprising a copper and TEOS;
providing a chemical mechanical polishing composition comprising a silanized colloidal silica particle, wherein the silanized colloidal silica particle comprises a reaction product of an epoxy functionality of the silanized colloidal silica particle with a nitrogen of an amine;
water;
optionally a chelating agent;
optionally a corrosion inhibitor;
optionally an oxidizing agent;
optionally a source of iron (III) ions;
optionally a surfactant;
optionally a defoaming agent;
optionally biocide; and
optionally a pH adjustor;
providing a chemical mechanical polishing pad, having a polishing surface; creating dynamic contact at an interface between the chemical mechanical polishing pad and the substrate; and dispensing the chemical mechanical polishing composition onto the polishing surface of the chemical mechanical polishing pad at or near the interface between the chemical mechanical polishing pad and the substrate; wherein at least some of the copper and at least some of the TEOS are polished away from the substrate.

5. The chemical mechanical polishing method of claim 4, wherein the silanized colloidal silica particle has the structure: 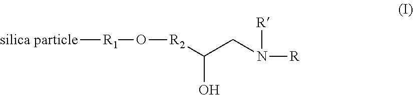
wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups on a nitrogen of the amino C₁-C₄ alkyl group include linear or branched C₁-C₄ alkyl, substituted or unsubstituted guanidyl group, wherein substituent groups on the substituted guanidyl group are chosen from C₁-C₂ alkyl on a nitrogen of the guanidyl group, a moiety having the formula:
H₂N—[—(CH₂)ₙ—NH—]ₘ—(CH₂)ₙ— (II)
wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.
